(19) United States
(12) Patent Application Publication
(10) Pub. No.: US 2009/0039509 A1
(43) Pub. Date: Feb. 12, 2009

(54) SEMICONDUCTOR DEVICE AND METHOD OF MANUFACTURING THE SAME

(75) Inventors: Manabu Tanabe, Osaka (JP); Hiroaki Fujimoto, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Osaka (JP)

(21) Appl. No.: 12/185,921

(22) Filed: Aug. 5, 2008

(30) Foreign Application Priority Data
Aug. 7, 2007 (JP) 2007-204825

(51) Int. Cl. H01L 23/488; H01L 21/44

(52) U.S. Cl. 257/738; 438/617; 257/E23.023; 257/E21.476

(57) ABSTRACT

A semiconductor device is provided which can prevent contacts between thin metal wires for electrically connecting the electrodes of a substrate with the electrodes of a semiconductor element. The semiconductor device of the present invention includes metal protrusions formed on the electrodes of the semiconductor element, the metal protrusions having lower hardness than the hardness of the thin metal wires. The metal protrusions are bonded to the thin metal wires.

### FIELD OF THE INVENTION

The present invention relates to a semiconductor device and a method of manufacturing the same.

### BACKGROUND OF THE INVENTION

In recent years, electronic equipment such as mobile communication equipment has become smaller with higher functionality and more functions, and in order to address this trend, semiconductor devices have been reduced in size with higher densities and more pins. For example, packaged semiconductor devices have been frequently used which have external terminals disposed in an area array format on the undersides of the semiconductor devices. Further, the electrodes of a packaged semiconductor chip have been disposed in multiple rows along the peripheries (outer edges) of the chip, like staggered arrangements and so on. Thus longer bonding wires have increasingly been used for electrically connecting the electrodes of a semiconductor chip with the electrodes of a package.

An example of such a packaged semiconductor device is a ball grid array (BGA) package. FIG. 8 shows a BGA package of the prior art.

As shown in FIG. 8, the BGA package includes a BGA substrate 40 (hereinafter, will be simply referred to as a substrate 40), electrodes 41 and 42 formed on the substrate 40, a semiconductor chip 43 fixed on the substrate 40, electrodes 44a and 44b formed on a surface of the semiconductor chip 43, and bonding wires 45 and 47 for electrically connecting the electrodes 44a and 44b of the semiconductor chip with the electrodes 41 and 42 of the substrate. The electrodes 44a and 44b of the semiconductor chip are bonded to joints made up of balls 46 and 48 formed on the ends of the bonding wires 45 and 47.

In such a BGA package, the bonding wires 45 are connected to the electrodes 44a disposed on the periphery of the semiconductor chip 43 and the bonding wires 47 are connected to the electrodes 44b disposed closer to the center of the semiconductor chip 43 than the electrodes 44a disposed on the periphery of the semiconductor chip 43. The loop heights of the bonding wires 45 are set as low as possible to keep distances between the bonding wires 45 and the bonding wires 47 (for example, see Japanese Patent Laid-Open No. 8-340018).

In this way, in semiconductor devices of the prior art, adjacent bonding wires are three-dimensionally arranged so as not to come into contact with each other.

Further, in the prior art, bonding wires contain gold (Au) as a major component to prevent damage on wiring and the like under the electrodes of a semiconductor chip when the bonding wires are bonded to the electrodes.

However, when bonding wires contain Au as a major component to prevent damage on wiring and the like in a semiconductor chip, it is difficult to keep the loop shapes of the bonding wires and the bonding wires may come into contact with each other. Such a contact reduces yields.

### DISCLOSURE OF THE INVENTION

The present invention is devised in view of the foregoing problem. An object of the present invention is to provide a semiconductor device which can prevent bonding wires from coming into contact with each other and improve yields, and a method of manufacturing the same.

In order to attain the object, a semiconductor device of the present invention includes: a substrate having a plurality of electrodes; a semiconductor element which is mounted on the substrate and has a plurality of electrodes; metal protrusions formed on the respective electrodes of the semiconductor element; and thin metal wires which are respectively bonded to the electrodes of the substrate and the metal protrusions to electrically connect the electrodes of the substrate with the electrodes of the semiconductor element, wherein the metal protrusions have hardness lower than the hardness of the thin metal wires bonded to the metal protrusions.

Furthermore, the electrodes of the substrate are bonded to joints made up of balls formed on the ends of the thin metal wires and the metal protrusions are bonded to joints formed by stitch bonding on the thin metal wires.

Moreover, the plurality of electrodes of the substrate are made up of a plurality of inner electrodes arranged in a row around a mounting region where the semiconductor element is mounted, and a plurality of outer electrodes arranged at least in a row farther from the mounting region than the inner electrodes; the plurality of electrodes of the semiconductor element are made up of a plurality of outer electrodes arranged in a row on the periphery of a major surface of the semiconductor element and a plurality of inner electrodes arranged at least in a row closer to the center of the major surface than the outer electrodes; the inner electrodes of the substrate and the metal protrusions on the inner electrodes of the semiconductor element are bonded to joints made up of balls formed on the ends of the thin metal wires; and the outer electrodes of the substrate and the metal protrusions on the outer electrodes of the semiconductor element are bonded to joints formed by stitch bonding on the thin metal wires.

Furthermore, the plurality of electrodes of the substrate are made up of a plurality of inner electrodes arranged in a row around a mounting region where the semiconductor element is mounted, and a plurality of outer electrodes arranged at least in a row farther from the mounting region than the inner electrodes; the outer electrodes of the substrate are bonded to joints made up of balls formed on the ends of the thin metal wires; the inner electrodes of the substrate are bonded to joints formed by stitch bonding on the thin metal wires; the plurality of electrodes of the semiconductor element are arranged in a row on the periphery of a major surface of the semiconductor element; and the plurality of metal protrusions are alternately bonded to joints made up of balls formed on the ends of the thin metal wires and joints formed by stitch bonding on the thin metal wires.

Moreover, the metal protrusions and the thin metal wires contain gold as a major component and the metal protrusions have a gold content larger than a gold content of the thin metal wires.

Further, the thin metal wires contain gold as a major component and the thin metal wires further contain palladium.

Moreover, the metal protrusions contain gold as a major component and the thin metal wires contain one of copper and aluminum as a major component.

A method of manufacturing a semiconductor device according to the present invention includes the steps of: forming metal protrusions on the electrodes of a semiconductor element mounted on a substrate; and bonding thin metal wires harder than the metal protrusions to the electrodes of the substrate and the metal protrusions.

Further, when the thin metal wires are bonded to the electrodes of the substrate and the metal protrusions, joints made up of balls formed on the ends of the thin metal wires are bonded to the electrodes of the substrate, and joints formed by stitch bonding on the thin metal wires are bonded to the metal protrusions.

Moreover, the step of bonding the thin metal wires to the electrodes of the substrate and the metal protrusions includes the steps of: bonding joints made up of balls formed on the ends of the thin metal wires to inner electrodes of the substrate, the inner electrodes being arranged in a row around a mounting region where the semiconductor element is mounted, and bonding joints formed by stitch bonding on the thin metal wires to the metal protrusions on outer electrodes of the semiconductor element, the outer electrodes being arranged in a row on the periphery of a major surface of the semiconductor element; and bonding joints made up of balls formed on the ends of the thin metal wires to the metal protrusions on inner electrodes of the semiconductor element, the inner electrodes being arranged at least in a row closer to the center of the major surface than the outer electrodes of the semiconductor element, and bonding joints formed by stitch bonding on the thin metal wires to outer electrodes of the substrate, the outer electrodes being arranged at least in a row farther from the mounting region than the inner electrodes of the substrate.

Further, the step of bonding the thin metal wires to the electrodes of the substrate and the metal protrusions includes a first step of bonding joints made up of balls formed on the ends of the thin metal wires to the metal protrusions on the electrodes of the semiconductor element, and bonding joints formed by stitch bonding on the thin metal wires to inner electrodes of the substrate, the inner electrodes being arranged in a row around a mounting region where the semiconductor element is mounted; and a second step of bonding joints made up of balls formed on the ends of the thin metal wires to outer electrodes of the substrate, the outer electrodes being arranged at least in a row farther from the mounting region than the inner electrodes of the substrate, and bonding joints formed by stitch bonding on the thin metal wires to the metal protrusions on the electrodes of the semiconductor element, wherein in the first and second steps, the joints made up of the balls formed on the ends of the thin metal wires and the joints formed by stitch bonding on the thin metal wires are alternately bonded to the metal protrusions on the electrodes of the semiconductor element, the electrodes being arranged in a row on the periphery of a major surface of the semiconductor element.

Moreover, the metal protrusions and the thin metal wires contain gold as a major component and the metal protrusions have a gold content larger than a gold content of the thin metal wires.

Further, the thin metal wires contain gold as a major component and the thin metal wires further contain palladium.

Moreover, the metal protrusions contain gold as a major component and the thin metal wires contain one of copper and aluminum as a major component.

The method further includes the steps of: bonding, to the electrodes of the semiconductor element, balls formed on the ends of thin metal wires having lower hardness than the thin metal wires for electrically connecting the electrodes of the substrate with the electrodes of the semiconductor element; and cutting, from the balls, the thin metal wires having lower hardness to form the metal protrusions.

According to the preferred embodiments of the present invention, the thin metal wires having high hardness are used for electrically connecting the electrodes of the substrate with the electrodes of the semiconductor element. Thus even when the thin metal wires become longer with an increasing number of pins in the semiconductor device, it is possible to keep the loop shapes of the thin metal wires and prevent the adjacent thin metal wires from coming into contact each other, thereby improving yields.

Further, by using the metal protrusions having low hardness, it is possible to reduce damage on wiring or an element under the electrodes of the semiconductor element when the metal protrusions are formed on the electrodes of the semiconductor element or when the thin metal wires are wire-bonded (ball bonding or stitch bonding) on the electrodes.

Moreover, in order to increase the hardness of the thin metal wires for electrically connecting the electrodes of the substrate with the electrodes of the semiconductor element, the content of a gold (Au), a major component, is reduced or the thin metal wires containing one of copper (Cu) and aluminum (Al) as a major component are used. Thus it is possible to reduce the amount of use of Au which is an extremely expensive material, thereby reducing the cost.

The semiconductor device of the present invention and the method of manufacturing the same are particularly useful as a semiconductor device which can prevent bonding wires from coming into contact with each other and is mounted in a small size and with a large number of pins in electronic equipment such as mobile communication equipment, and as a method of manufacturing the semiconductor device.

### BRIEF DESCRIPTION OF THE DRAWINGS

FIG. 1 is a process sectional view for explaining a method of manufacturing a semiconductor device according to a first embodiment of the present invention;

FIG. 2 is a process sectional view for explaining the method of manufacturing the semiconductor device according to the first embodiment of the present invention;

FIG. 3 is a process sectional view for explaining the method of manufacturing the semiconductor device according to the first embodiment of the present invention;

FIG. 4 is a process sectional view for explaining the method of manufacturing the semiconductor device according to the first embodiment of the present invention;

FIG. 5 is a sectional view schematically showing the configuration of a semiconductor device according to a second embodiment of the present invention;

FIG. 6 is a partially enlarged plan view schematically showing the configuration of a semiconductor device according to a third embodiment of the present invention;

FIG. 7 is a partially enlarged sectional view schematically showing the configuration of the semiconductor device according to the third embodiment of the present invention; and

FIG. 8 is a sectional view showing a semiconductor device of the prior art.

### DESCRIPTION OF THE EMBODIMENTS

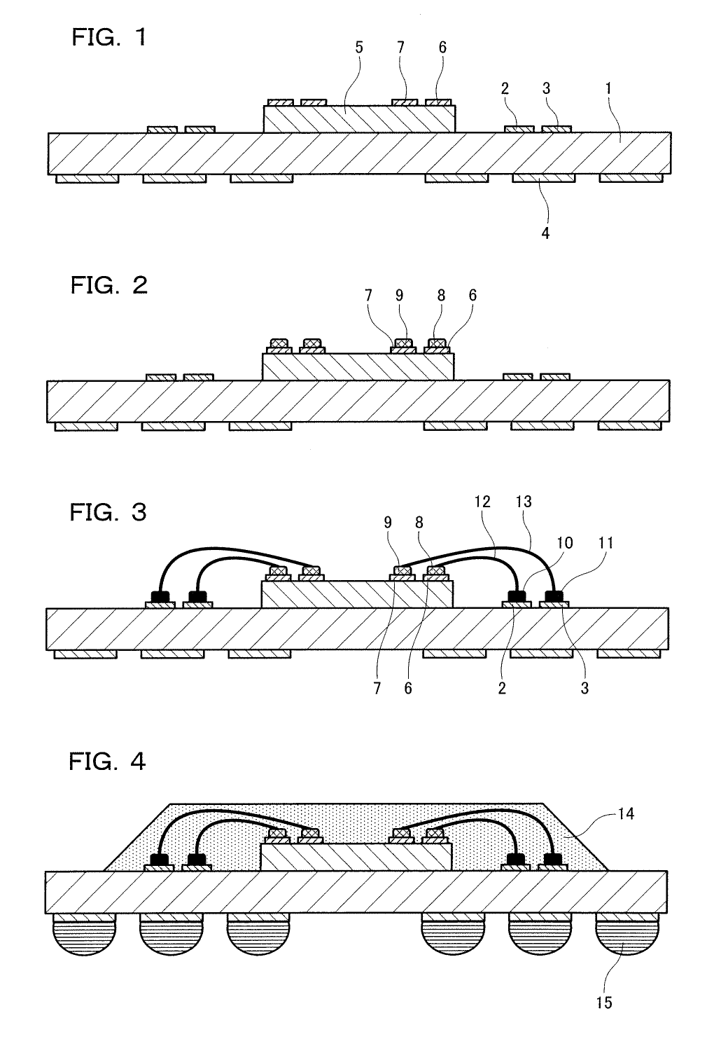

Embodiments of the present invention will now be described with reference to the accompanying drawings. The following will discuss a BGA package as an example. FIGS. 1 to 4 are sectional views showing the steps of manufacturing the BGA package which is a semiconductor device according to a first embodiment of the present invention.

First, as shown in FIG. 1, a semiconductor chip (semiconductor element) 5 having a plurality of electrodes 6 and 7 is mounted on a BGA substrate 1 (hereinafter, will be simply referred to as a substrate 1) having a plurality of electrodes 2 and 3. The substrate 1 is made of glass epoxy, BT resin, polyimide, and so on and is about 0.05 mm to 1.6 mm in thickness.

On the top surface of the substrate 1, the inner electrodes 2 and the outer electrodes 3 are formed. The inner electrodes 2 are arranged in a row around a mounting region where the semiconductor chip 5 is mounted, and the outer electrodes 3 are arranged in a row farther from the mounting region than the inner electrodes 2. The main conductor component of the electrodes 2 and 3 is copper (Cu) and so on and the electrodes 2 and 3 are about 5 μm to 35 μm in thickness. Further, the surfaces of the electrodes 2 and 3 are plated with Au and so on and are electrically connected to the electrodes 6 and 7 of the semiconductor chip 5.

In this configuration, the electrodes of the substrate 1 are arranged in two rows around the mounting region where the semiconductor chip 5 is mounted. The number of rows of the electrodes on the substrate is not limited to two and thus the number of rows (the number of rows of the outer electrodes) can be further increased.

On the underside of the substrate 1, external electrodes 4 are formed. The external electrodes 4 are electrically connected to the electrodes 2 and 3 of the substrate through vias and through holes (not shown) formed on the substrate 1.

The semiconductor chip 5 is fixed substantially at the center of the substrate 1 with a die bonding resin (not shown). The semiconductor chip 5 is fixed using an insulating resin which contains epoxy, polyimide and so on as major components, a conductive resin which contains Ag filler, and so on. The fixed portion is about 5 μm to 50 μm in thickness.

On the semiconductor chip 5, the outer electrodes 6 and the inner electrodes 7 are formed. The outer electrodes 6 are arranged in a row on the periphery of a major surface of the semiconductor chip 5 and the inner electrodes 7 are arranged in a row closer to the center of the major surface of the semiconductor chip 5 than the outer electrodes 6. Generally, the electrodes 6 and 7 are made of aluminum (Al), copper (Cu), and so on.

Although the electrodes of a semiconductor chip are generally arranged in a row on the periphery of the semiconductor chip, when the number of electrodes is increased in response to an increasing number of pins in a semiconductor device, the electrodes cannot be arranged only in a single row. Thus, in this case, the electrodes are arranged in multiple rows from the periphery to the inner side of the semiconductor chip. The number of rows of electrodes on a semiconductor element is not limited to two. The number of rows of the electrodes (the number of rows of inner electrodes) can be further increased with the number of pins.

Next, as shown in FIG. 2, protruding electrodes (metal protrusions) 8 and 9 are formed on the electrodes 6 and 7 of the semiconductor element. In this configuration, ball bonding is performed on the electrodes 6 and 7 of the semiconductor chip 5, balls (metal balls) formed on the ends of Au wires (thin metal wires) are bonded to the electrodes 6 and 7 of the semiconductor chip 5, and then the Au wires are cut from the balls directly on the balls, so that the protruding electrodes 8 and 9 are formed. The protruding electrodes 8 and 9 are about 30 μm to 100 μm in diameter and are about 5 μm to 50 μm in thickness. The protruding electrodes 8 and 9 and the electrodes 6 and 7 of the semiconductor element are bonded to each other by ultrasonic thermocompression bonding and so on. When the electrodes 6 and 7 of the semiconductor element are made of aluminum (Al), an Au—Al alloy is formed by ultrasonic thermocompression bonding at 50° C. to 300° C. with a load of about 5 g to 100 g.

By forming the protruding electrodes 8 and 9 with the Au wires having an Au content of at least 99.99 mass percent, it is possible to reduce the hardness of the protruding electrodes 8 and 9 and considerably reduce stress to the electrodes 6 and 7 when the protruding electrodes 8 and 9 are bonded to the electrodes 6 and 7 of the semiconductor element. Thus even when wiring and an element such as a transistor are disposed under the electrodes 6 and 7, the wiring and the element such as a transistor are not damaged.

Next, as shown in FIG. 3, bonding wires (thin metal wires) 12 harder than the protruding electrodes 8 are bonded to the inner electrodes 2 of the substrate 1 and the protruding electrodes 8 on the outer electrodes 6 of the semiconductor chip 5, and bonding wires (thin metal wires) 13 harder than the protruding electrodes 9 are bonded to the outer electrodes 3 of the substrate 1 and the protruding electrodes 9 on the inner electrodes 7 of the semiconductor chip 5, so that the electrodes 2 and 3 of the substrate 1 and the electrodes 6 and 7 of the semiconductor chip 5 are electrically connected to each other.

When the bonding wires are bonded, wire bonding is performed by ultrasonic thermocompression bonding and so on. To be specific, joints made up of balls (metal balls) 10 and 11 formed on the ends of the bonding wires 12 and 13 are bonded to the electrodes 2 and 3 of the substrate 1 by ball bonding. To the protruding electrodes 8 and 9, joints formed by stitch bonding on the bonding wires 12 and 13 are bonded by stitch bonding.

When the semiconductor device has a large number of pins, the bonding wires 12 and 13 are about 5 mm to 8 mm in length. The bonding wires 12 and 13 have a gold (Au) content of 99.00 mass percent which is smaller than the gold (Au) content of 99.99 mass percent of the protruding electrodes 8 and 9, or contain one of copper (Cu) and aluminum (Al) as a major component. In any case, the bonding wires 12 and 13 are harder than the protruding electrodes 8 and 9 and even when the bonding wires become longer, the loops of the bonding wires are not deformed and thus it is possible to prevent the bonding wires from contacting each other.

Moreover, even when the bonding wires 12 and 13 having high hardness are used, the bonding wires 12 and 13 and the semiconductor chip 5 are bonded by way of the protruding electrodes 8 and 9 having low hardness and thus it is possible to considerably reduce stress to wiring and an element such as a transistor which are formed under the electrodes 6 and 7 of the semiconductor chip 5. Therefore, it is possible to prevent a reduction in yields. When wires having an Au content of 99.00 mass percent are used as the bonding wires 12 and 13, it is preferable to add a metal such as palladium (Pd) to the bonding wires. Thus it is possible to obtain excellent connections.

Next, as shown in FIG. 4, a resin 14 is formed on the major surface where the semiconductor chip 5 is mounted, in order to mold the semiconductor chip 5, the bonding wires 12 and 13, and so on. Thereafter, balls 15 of solder and the like are formed on the external electrodes 4 of the substrate 1.

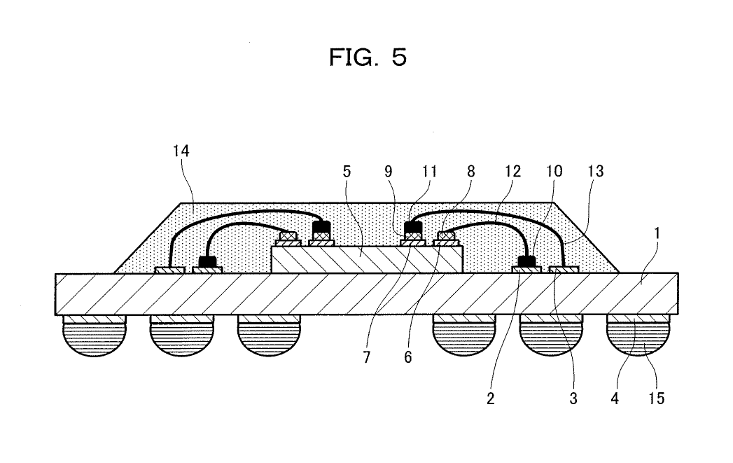

Referring to FIG. 5, the following will describe a BGA package which is a semiconductor device according to a second embodiment of the present invention. FIG. 5 is a sectional view showing the BGA package which is the semiconductor device according to the second embodiment of the present invention. Members corresponding to the members described in the first embodiment are indicated by the same reference numerals and the explanation thereof is omitted.

The second embodiment is different from the first embodiment in that joints made up of balls (metal balls) 10 formed on the ends of bonding wires 12 are bonded to inner electrodes 2 of a substrate 1, joints formed by stitch bonding on the bonding wires 12 are bonded to protruding electrodes 8 on outer electrodes 6 of a semiconductor chip 5, joints made up of balls (metal balls) 11 formed on the ends of bonding wires 13 are bonded to protruding electrodes 9 on inner electrodes 7 of the semiconductor chip 5, and joints formed by stitch bonding on the bonding wires 13 are bonded to outer electrodes 3 of the substrate 1.

In steps of manufacturing the BGA package, the step of bonding the bonding wires 12 and 13 to the electrodes 2 and 3 of the substrate 1 and the protruding electrodes 8 and 9 is different from the step of the first embodiment. To be specific, ball bonding is performed on the inner electrodes 2 of the substrate 1, the joints made up of the balls 10 formed on the ends of the bonding wires 12 are bonded to the inner electrodes 2, stitch bonding is performed on the protruding electrodes 8 on the outer electrodes 6 of the semiconductor chip 5, and the joints formed by stitch bonding on the bonding wires 12 are bonded to the protruding electrodes 8. Further, ball bonding is performed on the protruding electrodes 9 on the inner electrodes 7 of the semiconductor chip 5, the joints made up of the balls 11 formed on the ends of the bonding wires 13 are bonded to the protruding electrodes 9, stitch bonding is performed on the outer electrodes 3 of the substrate 1, and the joints formed by stitch bonding on the bonding wires 13 are bonded to the outer electrodes 3.

According to the second embodiment, it is possible to increase a distance between the bonding wires 12 and 13 near the protruding electrodes 8 and 9 and reduce failures caused by contact between the bonding wires, thereby improving yields.

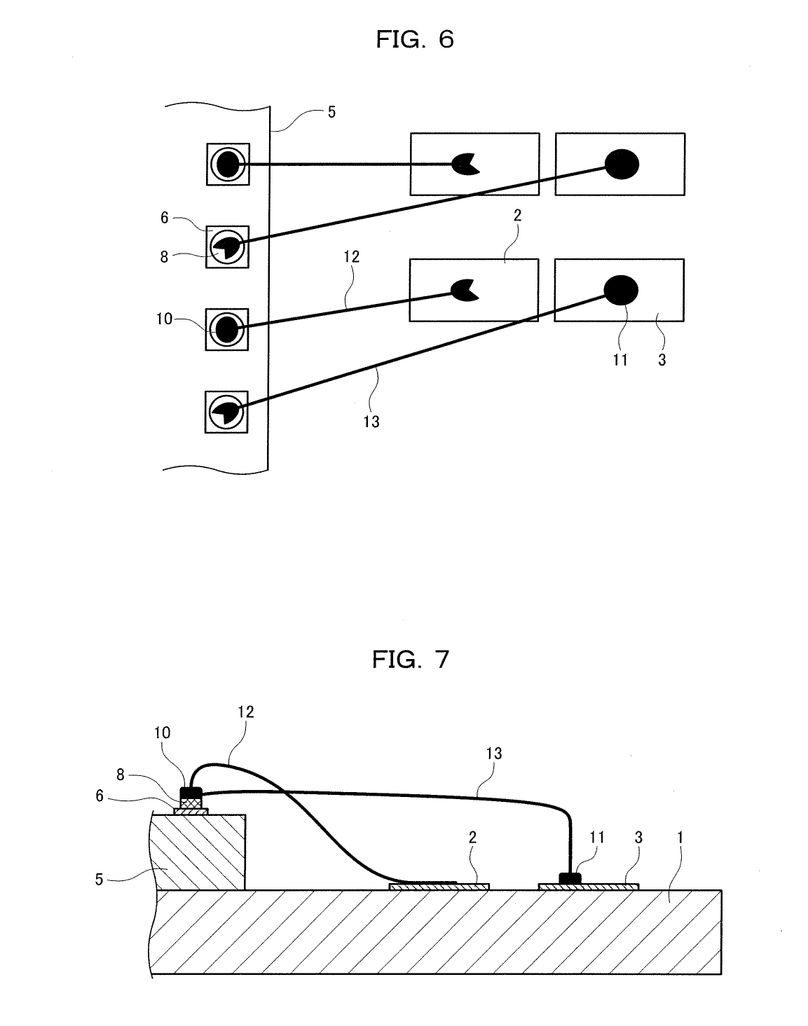

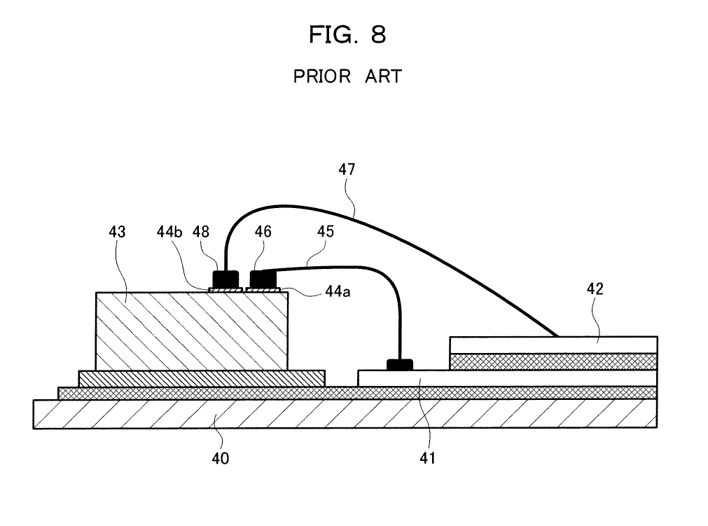

Referring to FIGS. 6 and 7, the following will describe a BGA package which is a semiconductor device according to a third embodiment of the present invention. FIG. 6 is a partially enlarged plan view showing the BGA package which is the semiconductor device according to the third embodiment of the present invention. FIG. 7 is a partially enlarged sectional view showing the BGA package which is the semiconductor device according to the third embodiment of the present invention. Members corresponding to the members described in the first embodiment are indicated by the same reference numerals and the explanation thereof is omitted.

The third embodiment is different from the first embodiment in that a semiconductor chip 5 only has electrodes 6 arranged in a single row on the periphery of a major surface of the semiconductor chip 5. Further, the third embodiment is different from the first embodiment in that joints formed by stitch bonding on bonding wires 12 are bonded to inner electrodes 2 of a substrate 1 and joints made up of balls (metal balls) 11 formed on the ends of bonding wires 13 are bonded to outer electrodes 3 of the substrate 1. Moreover, the third embodiment is different from the first embodiment in that joints made up of balls (metal balls) 10 formed on the ends of the bonding wires 12 connected to the inner electrodes 2 of the substrate 1 and joints formed by stitch bonding on the bonding wires 13 connected to the outer electrodes 3 of the substrate 1 are alternately bonded to protruding electrodes 8 on the electrodes 6 of the semiconductor chip 5.

In steps of manufacturing the BGA package, the step of bonding the bonding wires 12 and 13 to the electrodes 2 and 3 of the substrate 1 and the protruding electrodes 8 is different from the step of the first embodiment. To be specific, ball bonding is performed on the protruding electrodes 8 on the electrodes 6 of the semiconductor chip 5, the joints made up of the balls 10 formed on the ends of the bonding wires 12 are bonded to the protruding electrodes 8, stitch bonding is performed on the inner electrodes 2 of the substrate 1, and the joints formed by stitch bonding on the bonding wires 12 are bonded to the inner electrodes 2 (first step). Further, ball bonding is performed on the outer electrodes 3 of the substrate 1, the joints made up of the balls 11 formed on the ends of the bonding wires 13 are bonded to the outer electrodes 3, stitch bonding is performed on the protruding electrodes 8 on the electrodes 6 of the semiconductor chip 5, and the joints formed by stitch bonding on the bonding wires 13 are bonded to the protruding electrodes 8 (second step). In the first and second steps, the joints made up of the balls 10 formed on the ends of the bonding wires 12 connected to the inner electrodes 2 of the substrate 1 and the joints formed by stitch bonding on the bonding wires 13 connected to the outer electrodes 3 of the substrate 1 are alternately bonded to the protruding electrodes 8 on the electrodes 6 of the semiconductor chip 5.

According to the third embodiment, ball bonding is performed alternately on the protruding electrodes 8 of the semiconductor chip 5. Thus during the bonding, an inclined portion of a capillary does not come into contact with an adjacent bonding wire and the electrodes 6 of the semiconductor chip 5 can be disposed with a small pitch, so that a high-density package can be obtained.

Of the electrodes of the substrate 1, the outer electrodes 3 farther from the semiconductor chip 5 are ball bonded. Thus it is possible to increase the rising angles of the bonding wires 13 on the outer electrodes 3. Therefore, even when the outer electrodes 3 of the substrate 1 are disposed near the inner electrodes 2 which are close to the semiconductor chip 5, the bonding wires 13 and the inner electrodes 2 of the substrate 1 do not come into contact with each other, so that the bonding wires 13 can be shortened and the cost can be reduced.

The first to third embodiments described examples in which the present invention is applied to BGA packages. As a matter of course, the present invention is similarly applicable to a QFP using a lead frame, and other types of packages.

What is claimed is:

1. A semiconductor device, comprising:
a substrate having a plurality of electrodes;
a semiconductor element which is mounted on the substrate and has a plurality of electrodes;
metal protrusions formed on the respective electrodes of the semiconductor element; and
thin metal wires which are respectively bonded to the electrodes of the substrate and the metal protrusions to electrically connect the electrodes of the substrate with the electrodes of the semiconductor element,
wherein the metal protrusions have hardness lower than hardness of the thin metal wires bonded to the metal protrusions.

2. The semiconductor device according to claim 1, wherein the electrodes of the substrate are bonded to joints made up of balls formed on ends of the thin metal wires and the metal protrusions are bonded to joints formed by stitch bonding on the thin metal wires.

3. The semiconductor device according to claim 1, wherein the plurality of electrodes of the substrate are made up of a plurality of inner electrodes arranged in a row around a mounting region where the semiconductor element is mounted, and a plurality of outer electrodes arranged at least in a row farther from the mounting region than the inner electrodes,
the plurality of electrodes of the semiconductor element are made up of a plurality of outer electrodes arranged in a row on a periphery of a major surface of the semiconductor element and a plurality of inner electrodes arranged at least in a row closer to a center of the major surface than the outer electrodes,
the inner electrodes of the substrate and the metal protrusions on the inner electrodes of the semiconductor element are bonded to joints made up of balls formed on ends of the thin metal wires, and
the outer electrodes of the substrate and the metal protrusions on the outer electrodes of the semiconductor element are bonded to joints formed by stitch bonding on the thin metal wires.

4. The semiconductor device according to claim 1, wherein the plurality of electrodes of the substrate are made up of a plurality of inner electrodes arranged in a row around a mounting region where the semiconductor element is mounted, and a plurality of outer electrodes arranged at least in a row farther from the mounting region than the inner electrodes,
the outer electrodes of the substrate are bonded to joints made up of balls formed on ends of the thin metal wires,
the inner electrodes of the substrate are bonded to joints formed by stitch bonding on the thin metal wires,
the plurality of electrodes of the semiconductor element are arranged in a row on a periphery of a major surface of the semiconductor element, and
the plurality of metal protrusions are alternately bonded to joints made up of balls formed on ends of the thin metal wires and joints formed by stitch bonding on the thin metal wires.

5. The semiconductor device according to claim 1, wherein the metal protrusions and the thin metal wires contain gold as a major component and the metal protrusions have a gold content larger than a gold content of the thin metal wires.

6. The semiconductor device according to claim 1, wherein the thin metal wires contain gold as a major component and the thin metal wires further contain palladium.

7. The semiconductor device according to claim 1, wherein the metal protrusions contain gold as a major component and the thin metal wires contain one of copper and aluminum as a major component.

8. A method of manufacturing a semiconductor device, comprising the steps of:
forming metal protrusions on electrodes of a semiconductor element mounted on a substrate; and
bonding thin metal wires harder than the metal protrusions to electrodes of the substrate and the metal protrusions.

9. The method of manufacturing a semiconductor device according to claim 8, wherein when the thin metal wires are bonded to the electrodes of the substrate and the metal protrusions, joints made up of balls formed on ends of the thin metal wires are bonded to the electrodes of the substrate, and joints formed by stitch bonding on the thin metal wires are bonded to the metal protrusions.

10. The method of manufacturing a semiconductor device according to claim 8, wherein the step of bonding the thin metal wires to the electrodes of the substrate and the metal protrusions comprises the steps of:
bonding joints made up of balls formed on ends of the thin metal wires to inner electrodes of the substrate, the inner electrodes being arranged in a row around a mounting region where the semiconductor element is mounted, and bonding joints formed by stitch bonding on the thin metal wires to the metal protrusions on outer electrodes of the semiconductor element, the outer electrodes being arranged in a row on a periphery of a major surface of the semiconductor element; and
bonding joints made up of balls formed on ends of the thin metal wires to the metal protrusions on inner electrodes of the semiconductor element, the inner electrodes being arranged at least in a row closer to a center of the major surface than the outer electrodes of the semiconductor element, and bonding joints formed by stitch bonding on the thin metal wires to outer electrodes of the substrate, the outer electrodes being arranged at least in a row farther from the mounting region than the inner electrodes of the substrate.

11. The method of manufacturing a semiconductor device according to claim 8, wherein the step of bonding the thin metal wires to the electrodes of the substrate and the metal protrusions comprises:
a first step of bonding joints made up of balls formed on ends of the thin metal wires to the metal protrusions on the electrodes of the semiconductor element, and bonding joints formed by stitch bonding on the thin metal wires to inner electrodes of the substrate, the inner electrodes being arranged in a row around a mounting region where the semiconductor element is mounted; and
a second step of bonding joints made up of balls formed on ends of the thin metal wires to outer electrodes of the substrate, the outer electrodes being arranged at least in a row farther from the mounting region than the inner electrodes of the substrate, and bonding joints formed by stitch bonding on the thin metal wires to the metal protrusions on the electrodes of the semiconductor element,
wherein in the first and second steps, the joints made up of the balls formed on the ends of the thin metal wires and the joints formed by stitch bonding on the thin metal wires are alternately bonded to the metal protrusions on the electrodes of the semiconductor element, the electrodes being arranged in a row on a periphery of a major surface of the semiconductor element.

12. The method of manufacturing a semiconductor device according to claim 8, wherein the metal protrusions and the thin metal wires contain gold as a major component and the metal protrusions have a gold content larger than a gold content of the thin metal wires.

13. The method of manufacturing a semiconductor device according to claim 8, wherein the thin metal wires contain gold as a major component and the thin metal wires further contain palladium.

14. The method of manufacturing a semiconductor device according to claim 8, wherein the metal protrusions contain gold as a major component and the thin metal wires contain one of copper and aluminum as a major component.

15. The method of manufacturing a semiconductor device according to claim 8, further comprising the steps of:
bonding, to the electrodes of the semiconductor element, balls formed on ends of thin metal wires having lower hardness than the thin metal wires for electrically connecting the electrodes of the substrate with the electrodes of the semiconductor element; and
cutting, from the balls, the thin metal wires having lower hardness to form the metal protrusions.
